(19) United States
(12) Patent Application Publication
(10) Pub. No.: US 2025/0179641 A1
(43) Pub. Date: Jun. 5, 2025

(54) SEMICONDUCTOR DEVICE

(71) Applicant: JIANGSU LEADMICRO NANO TECHNOLOGY CO., LTD., Wuxi (CN)

(72) Inventors: Ren ZHOU, Wuxi (CN); Dezan YANG, Wuxi (CN); Biao WU, Wuxi (CN); Junichi ARAMI, Wuxi (CN)

(21) Appl. No.: 18/843,363

(22) PCT Filed: Apr. 21, 2023
(86) PCT No.: PCT/CN2023/089912

§ 371 Date: Sep. 3, 2024

(30) Foreign Application Priority Data
May 18, 2022 (CN) 202210551680.0

(51) Int. Cl. C23C 16/46; C23C 16/44; C23C 16/455; C23C 16/458; H01L 21/683

(52) U.S. Cl. CPC C23C 16/46; C23C 16/4408; C23C 16/45544; C23C 16/4586; H01L 21/6833

(57) ABSTRACT

The present disclosure relates to a semiconductor device. In embodiments, a semiconductor device includes: a first base, including a front surface and a back surface, and including a first main gas inlet channel, a second main gas inlet channel, a first split channel, and a first through hole; a second base, connected to the back surface of the first base, and including the first main gas inlet channel, the second main gas inlet channel, a second split channel and a second through hole; and a base cover plate, connected to the front surface of the first base, and including the first main gas inlet channel, the second main gas inlet channel, a third split channel, and a third through hole, the base cover plate receiving a first gas through the first main gas inlet channel and receiving a second gas through the second main gas inlet channel, where the first gas and the second gas are delivered to the front surface of the first base through the first through hole and the third through hole, and the first gas and the second gas are delivered to the back surface of the first base through the first through hole and the second through hole.

### BACKGROUND OF THE INVENTION

### 1. Field of the Invention

The present disclosure substantially relates to semiconductor devices, and in particular, to a multi-chamber laminar flow-type film deposition apparatus.

### 2. Description of the Related Art

The semiconductor device may perform a deposition coating process on a wafer, for example, processing techniques such as atomic layer deposition (ALD) coating, chemical vapor deposition (CVD), and plasma enhanced chemical vapor deposition (PECVD).

A film deposition apparatus or device may be fed with one or more reaction sources (also referred to as reactive gases or process gases) to perform deposition coating a wafer located in the film deposition apparatus or device.

### SUMMARY OF THE INVENTION

Embodiments of the present disclosure provide a semiconductor device, including: a first base, including a front surface and a back surface, and including a first main gas inlet channel, a second main gas inlet channel, a first split channel, and a first through hole; a second base, connected to the back surface of the first base, and including the first main gas inlet channel, the second main gas inlet channel, a second split channel and a second through hole; and a base cover plate, connected to the front surface of the first base, and including the first main gas inlet channel, the second main gas inlet channel, a third split channel, and a third through hole, the base cover plate receiving a first gas through the first main gas inlet channel and receiving a second gas through the second main gas inlet channel, where the first gas and the second gas are delivered to the front surface of the first base through the first through hole and the third through hole, and the first gas and the second gas are delivered to the back surface of the first base through the first through hole and the second through hole.

Some other embodiments of the present disclosure provide a semiconductor device, including: a gas inlet, configured to receive one or more gases; a cavity, connected to the gas inlet and including a plurality of bases; a gas outlet, communicating with the plurality of bases inside the cavity; and a heating device, arranged inside the plurality of bases of the cavity, the heating device including a plurality of chucks, the plurality of chucks being arranged corresponding to the plurality of bases, to enable the one or more gases to flow by the plurality of bases and the plurality of chucks into the gas outlet.

It should be understood that the broad forms of the present invention and respective features thereof may be used in combination, interchangeably and/or independently, and are not used intended to limit the reference to a single broad form.

### BRIEF DESCRIPTION OF THE DRAWINGS

The aspects of the present disclosure will become more comprehensible from the following detailed implementations with reference to the accompanying drawings. It should be noted that, various features may not be drawn to scale. Actually, the sizes of the various features may be increased or reduced arbitrarily for the purpose of clear description.

FIG. 1 is a cross-sectional view of a semiconductor device according to some embodiments of the present disclosure;

FIG. 2 is a cross-sectional view of a semiconductor device according to another embodiment of the present disclosure;

FIG. 3A is a side view of an external structure of a semiconductor device according to another embodiment of the present disclosure;

FIG. 3B is a cross-sectional view of the semiconductor device shown in FIG. 3A;

FIG. 3C is a schematic three-dimensional diagram of a heater according to some embodiments of the present disclosure;

FIG. 3D is a cross-sectional view of the heater shown in FIG. 3C;

FIG. 3E is a schematic three-dimensional diagram of a cavity according to some embodiments of the present disclosure;

FIG. 3F is a cross-sectional view of a cavity and a heater according to some embodiments of the present disclosure;

FIG. 3G is another cross-sectional view of a cavity and a heater according to some embodiments of the present disclosure;

FIG. 3H is a top view of a base according to some embodiments of the present disclosure; and

FIG. 4 is a schematic diagram of operation of a semiconductor device according to some embodiments of the present disclosure.

### PREFERRED EMBODIMENT OF THE PRESENT INVENTION

The following disclosure provides many different embodiments or examples for implementing different features of the provided subject matter. Specific examples of components and arrangements are described below. Certainly, these descriptions are merely examples and are not intended to be limiting. In this application, in the following descriptions, the description of the first feature being formed on or above the second feature may include an embodiment formed by direct contact between the first feature and the second feature, and may further include an embodiment in which an additional feature may be formed between the first feature and the second feature to enable the first feature and the second feature to be not in direct contact. In addition, in this application, reference numerals and/or letters may be repeated in examples. This repetition is for the purpose of simplification and clarity, and does not indicate a relationship between the described various embodiments and/or configurations.

The embodiments of the present application are described in detail below. However, it should be understood that many applicable concepts provided by the present disclosure may be implemented in a plurality of specific environments. The described specific embodiments are only illustrative and do not limit the scope of the present disclosure.

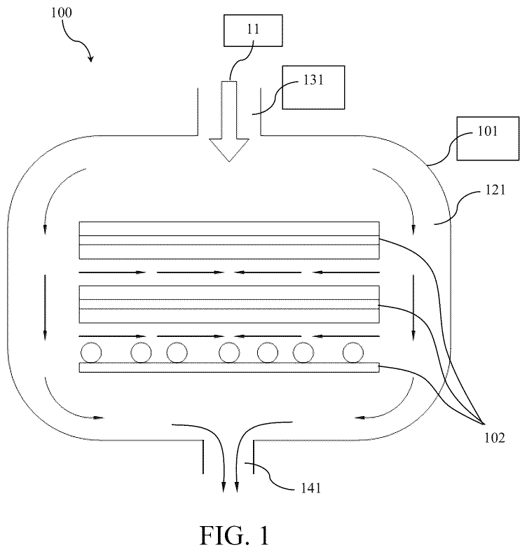

FIG. 1 is a cross-sectional view of a semiconductor device according to some embodiments of the present disclosure.

Referring to FIG. 1, a semiconductor device (100), for example, may include a cavity (101). The cavity (101) may internally include a chamber (121) and a gas inlet channel (131). One or more to-be-processed wafers (102) may be accommodated inside the chamber (121), and each wafer (102) includes upper and lower surfaces. An inner wall of the cavity (101) may be heated in any manner to form an inner wall heater, to heat the wafer (102) inside the chamber (121), and to promote deposition coating.

A gas (11) (indicated by a single arrow in FIG. 1) may include one or more reaction sources (not shown in FIG. 1), and may be fed into the chamber (121) through a gas inlet channel (131) above the cavity (101). The gas (11) fed into the chamber (121) may further circulate inside the chamber (121), to diffuse to the upper and lower surfaces of each to-be-processed wafer (102), and perform deposition coating on the upper and lower surfaces of each wafer (102). The residual gas (11) that does not perform deposition coating on the wafer (102) may be further discharged from the chamber (121) through a gas exhaust port (141) below the cavity (101).

During deposition coating, there is no forced flow of the gas (11) at the upper and lower surfaces of each wafer (102), and instead, diffusion of the gas is utilized to deliver the gas (11) to the upper and lower surfaces of each wafer (102). To ensure the uniformity of the film, a residence time of the gas (11) inside the chamber (121) can be appropriately increased. Increasing the residence time of the gas inside the chamber may be, for example (but not limited to), extending a takt time of a deposition coating reaction.

Because the upper and lower surfaces of each to-be-processed wafer (102) are both exposed to the gas (11), the semiconductor device (100) shown in FIG. 1 is suitable for an application in which coating needs to be performed on both upper and lower surfaces of a wafer.

In addition, because the inner wall heater of the cavity (101) is used to provide heating for wafers instead of providing independent heating for each wafer, a preheating time of the cavity (101) may be extended, to further reduce a temperature difference between different parts of a same wafer surface and reduce a temperature difference between wafers.

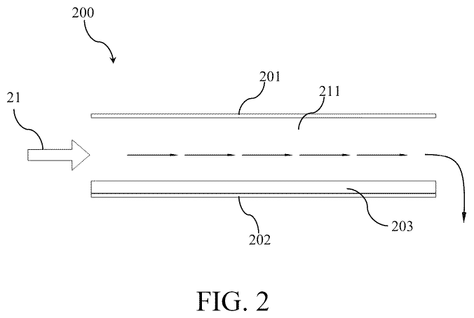

FIG. 2 is a cross-sectional view of a semiconductor device according to another embodiment of the present disclosure.

A semiconductor device (200) shown in FIG. 2 may use a cavity plate (201) and a cavity plate (202) to define a transverse gas flow channel (211). Therefore, the semiconductor device (200) may also be referred to as having a single-layer cross-flow structure.

A single to-be-processed wafer (203) is placed on the cavity plate (202). A gas (21) (as indicated by a single arrow in FIG. 2) may enter the transverse gas flow channel (211) from one side of the cavity (201), and be discharged from the transverse gas flow channel (211) from the other side of the cavity (201).

In this way, the semiconductor device (200) shown in FIG. 2 does not rely on diffusion of the gas (21) on the surfaces of the wafer (203), and instead, forces the gas (21) to flow in a single direction (for example, the left-to-right direction shown in FIG. 2) transversely through the upper surface of the wafer (203), to perform deposition coating on the upper surface of the wafer (203). Therefore, in the semiconductor device (200) shown in FIG. 2, the forced gas (21) may implement more uniform deposition coating on the upper surface of the wafer (203). No deposited coating is formed on the lower surface of the wafer (203).

Because only a single wafer (203) is processed, the production capacity of the semiconductor device (200) shown in FIG. 2 is limited to some extent.

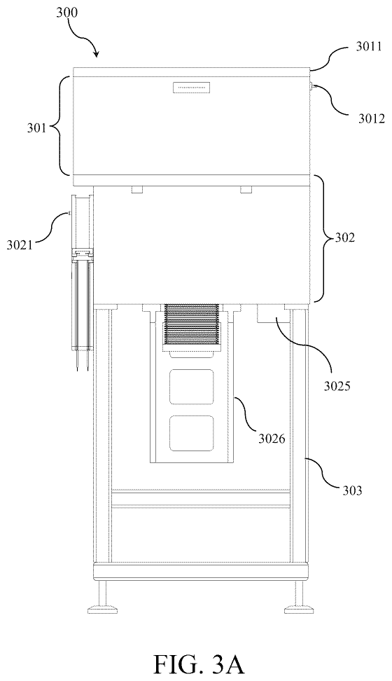

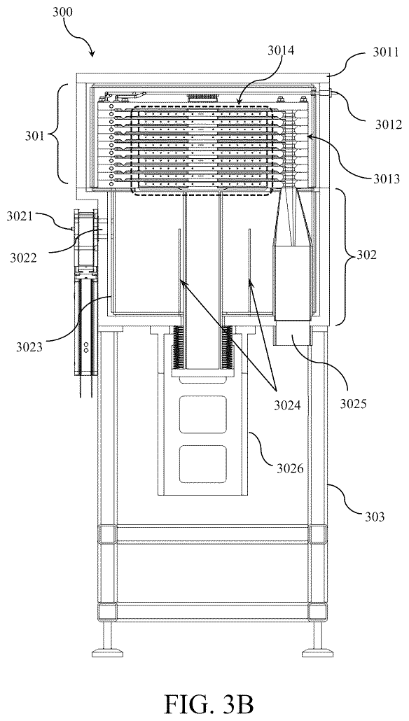

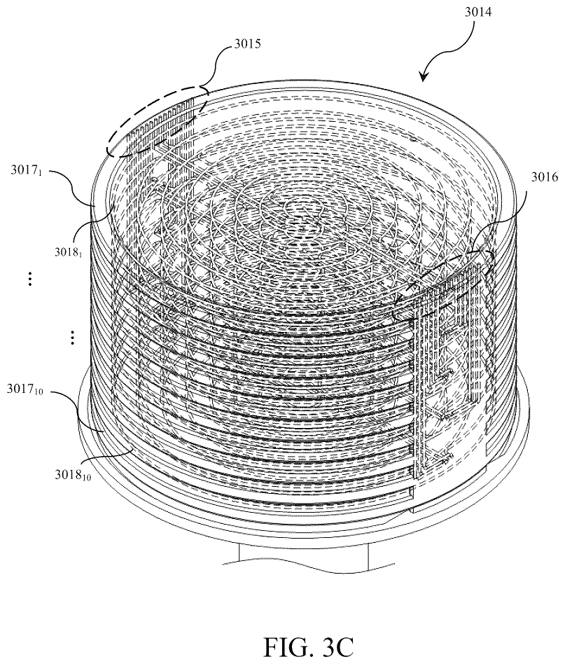

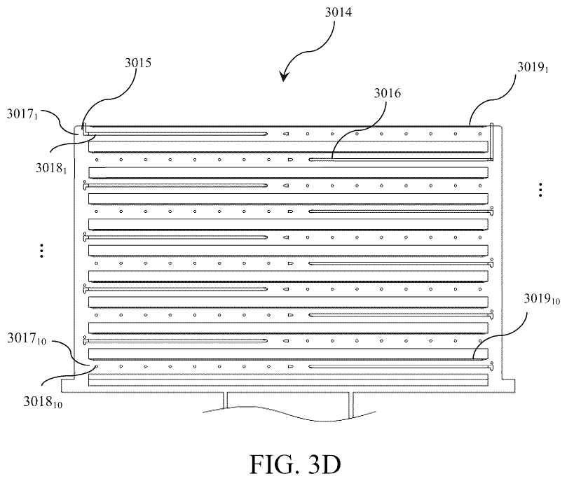

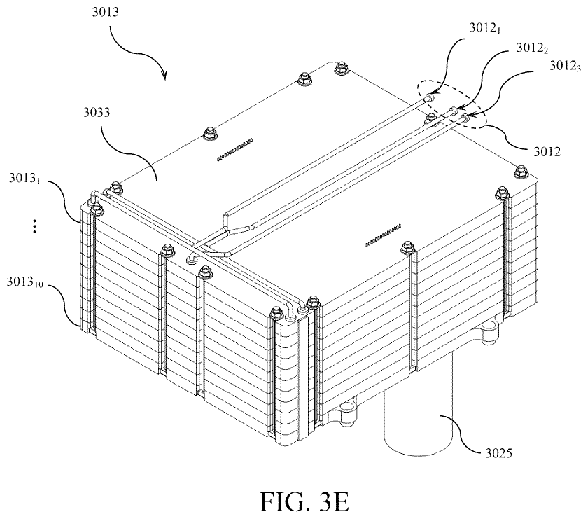

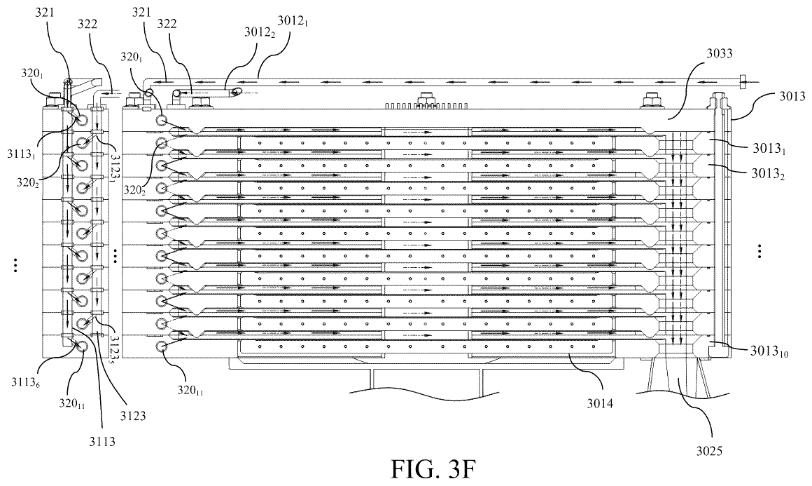

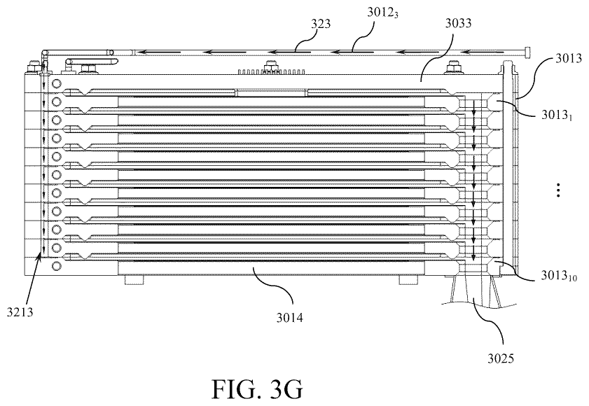

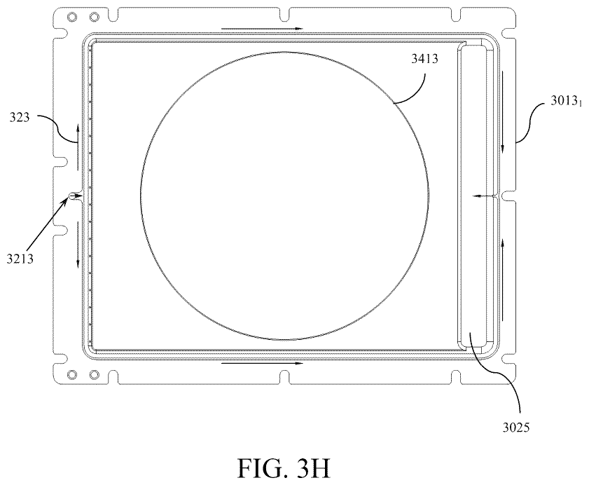

FIG. 3A is a side view of an external structure of a semiconductor device according to another embodiment of the present disclosure.

A semiconductor device (300) may include a cavity (301), a cavity (302), and a frame (303) configured to support the cavity (301) and the cavity (302).

The cavity (301) may include a cover plate (3011) and a gas inlet (3012) leading to the interior of the cavity (301).

The cavity (302) may be, for example, connected to the cavity (301) by a bolt, and communicate with the cavity (301). The cavity (302) may specifically include a valve body (3021), a mechanism (3026), and a gas exhaust port (3025).

It should be understood that the cavity (301) and the cavity (302) may also be implemented by a single cavity, and are not limited to the split-type structure shown in FIG. 3A. The internal structure of the semiconductor device (300) shown in FIG. 3A is described below in detail.

FIG. 3B is a cross-sectional view of the semiconductor device shown in FIG. 3A.

Referring to FIG. 3B, in the semiconductor device (300), the cavity (301) may include a cavity (3013), and the cavity (3013) may accommodate a heater (3014) (for example, the part indicated by a dashed line box in FIG. 3B). The heater (3014) may be connected to a mechanism (3026). The heater (3014) may move under the action of the mechanism (3026), to move into or out of the cavity (3013).

The cavity (3013) may communicate with the gas inlet (3012) to receive the gas through the gas inlet (3012). The cavity (3013) may communicate with the gas exhaust port (3025) to discharge the gas. It should be understood that, the cavity (3013) may be a multi-layer cavity. The heater (3014) may be a multi-layer heater.

The cavity (302) may include a wafer delivery port (3022). The cavity (302) may include a jacking rod (3024). The wafer delivery port (3022) may be opened or closed under the control of the valve body (3021). The to-be-processed wafer (not shown in FIG. 3B) may be delivered into or out of the cavity (302) through the wafer delivery port (3022).

When a to-be-processed wafer (not shown in FIG. 3B) needs to be delivered into or out of the heater (3014), the heater (3014) may be moved to the vicinity of wafer delivery port (3022) under the action of the mechanism (3026), and with the help of the jacking rod (3024), the wafer is placed on the heater (3014) or the wafer is jacked from the heater (3014).

The inner wall heater (3023) may be located on the inner wall of the cavity (301). The inner wall heater (3023) may be located on the inner wall of the cavity (301) and/or the inner wall of the cavity (302). The inner wall heater (3023) may be located on the inner walls of the cavity (301) and the cavity (302). The inner wall heater (3023) may provide heating for the to-be-processed wafer.

FIG. 3C is a schematic three-dimensional diagram of a heater according to some embodiments of the present disclosure.

Referring to FIG. 3C, the heater (3014) may include a chuck (3017₁), a chuck (3017₂), a chuck (3017₃), a chuck (3017₄), a chuck (3017₅), a chuck (3017₆), a chuck (3017₇), a chuck (3017₈), a chuck (3017₉), and a chuck (3017₁₀). A wafer may be placed on each of the chuck (3017₁) to the chuck (3017₁₀).

A heating wire (3018₁), a heating wire (3018₂), a heating wire (3018₃), a heating wire (3018₄), a heating wire (3018₅), a heating wire (3018₆), a heating wire (3018₇), a heating wire (3018₈), a heating wire (3018₉), and a heating wire (3018₁₀) are respectively arranged inside the corresponding chuck (3017₁) to chuck (3017₁₀). The heating wire (3018₁), the heating wire (3018₂), the heating wire (3018₃), the heating wire (3018₄), the heating wire (3018₅), the heating wire (3018₆), the heating wire (3018₇), the heating wire (3018₈), the heating wire (3018₉), and the heating wire (3018₁₀) are respectively arranged in the vicinity of the corresponding chuck (3017₁) to chuck (3017₁₀). For example, the heating wire (3018₅) may be arranged inside the corresponding chuck (3017₅), to heat a wafer placed on the chuck (3017₅). For example, the heating wire (3018₇) may be arranged in the vicinity of the corresponding chuck (3017₇), to heat a wafer placed on the chuck (3017₇).

Each of the heating wire (3018₁) to the heating wire (3018₁₀) may be connected to a lead wire (3015). Each of the heating wire (3018₁) to the heating wire (3018₁₀) may be connected to a lead wire (3016). Each of the heating wire (3018₁) to the heating wire (3018₁₀) may receive a signal (for example, a temperature control signal) through the lead wire (3015). Each of the heating wire (3018₁) to the heating wire (3018₁₀) may receive a signal (for example, a temperature control signal) through the lead wire (3016). The lead wire (3015) may extend to a surface of the heater (3014), to receive the signal. The lead wire (3016) may extend to a surface of the heater (3014), to receive the signal.

It should be understood that, the heating wire (3018₁) to the heating wire (3018₁₀) may be replaced with any heating component, to heat corresponding chucks and wafers thereon.

It should still be understood that, in another embodiment of the present disclosure, the heater (3014) may include, not limited to, 10 chucks (that is, the chuck (3017₁) to the chuck (3017₁₀)) shown in FIG. 3C, and may include more than 10 or less than 10 chucks. In another embodiment of the present disclosure, one corresponding heating component may be arranged for each chuck. In another embodiment of the present disclosure, a plurality of corresponding heating components may be arranged for each chuck. In another embodiment of the present disclosure, one corresponding heating component may be arranged for each plurality of chucks.

In addition, the heating wire may not be limited to being wound or formed as shown in FIG. 3C provided that it can heat the chuck.

In this way, not only the to-be-processed wafer as a whole can be heated and/or preheated by the inner wall heaters (3023) on the inner walls of the cavity (301) and the cavity (302), but also each wafer can be heated by its corresponding chuck independently.

The independent heating structure shown in FIG. 3C helps further improve the temperature uniformity everywhere on the same wafer surface and the temperature uniformity between wafers, thereby further improving the quality of the coating.

FIG. 3D is a cross-sectional view of the heater shown in FIG. 3C.

Referring to FIG. 3D, wafers (3019₁), (3019₂), (3019₃), (3019₄), (3019₅), (3019₆), (3019₇), (3019₈), and (3019₉), and a wafer (3019₁₀) are respectively placed on the chuck (3017₁) to the chuck (3017₁₀) of the heater (3014).

Because the heating wire (3018₁) to the heating wire (3018₁₀) are respectively arranged inside all the chuck (3017₁) to the chuck (3017₁₀), the wafer (3019₁) to the wafer (3019₁₀) may be respectively heated by the heating wire (3018₁) to the heating wire (3018₁₀) in a temperature-independently controllable manner.

An independent temperature control signal may be received through the lead wire (3015) and the lead wire (3016) that lead to an upper surface of the heater (3014). In the embodiment shown in FIG. 3D, heating wires in the chuck (3017₁), the chuck (3017₃), the chuck (3017₅), the chuck (3017₇), and the chuck (3017₉) of odd-numbered layers may be led out through the lead wire (3015). In the embodiment shown in FIG. 3D, heating wires in the chuck (3017₂), the chuck (3017₄), the chuck (3017₆), the chuck (3017₈), and the chuck (3017₁₀) of even-numbered layers may be led out through the lead wire (3016). However, it should be understood that, in another embodiment, the heating wires in the chucks of the heater (3014) may be led out to other positions of the heater (3014) in any other manner.

FIG. 3E is a schematic three-dimensional diagram of a cavity according to some embodiments of the present disclosure. For example, the heater (3014) shown in FIG. 3C may be accommodated inside the cavity (3013) shown in FIG. 3E.

Referring to FIG. 3E, the cavity (3013) may include a base cover plate (3033) as well as a base (3013₁), a base (3013₂), a base (3013₃), a base (3013₄), a base (3013₅), a base (3013₆), a base (3013₇), a base (3013₈), a base (3013₉), and a base (3013₁₀). The bases may be connected to each other, for example, by bolts.

The gas inlet (3012) may include a gas inlet (3012₁), a gas inlet (3012₂), and a gas inlet (3012₃). The gas (for example, the residual gas after the coating process is completed) may be discharged out of the cavity (3013) through the gas exhaust port (3025).

It should be understood that, in another embodiment of the present disclosure, the cavity (3013) may include a quantity of bases (that is, the base (3013₁) to the base (3013₁₀)), where the quantity is different from that shown in FIG. 3E.

It should still be understood that, in another embodiment of the present disclosure, the cavity (3013) may be provided with a quantity of gas inlets, where the quantity is different from that shown in FIG. 3E.

FIG. 3F is a cross-sectional view of a cavity and a heater according to some embodiments of the present disclosure.

For example, the heater (3014) shown in FIG. 3C or FIG. 3D may be accommodated inside the cavity (3013) shown in FIG. 3E, and a cross-sectional view after the heater (3014) is accommodated inside the cavity (3013) is shown in FIG. 3F. Upper surfaces of the base (3013₁) to the base (3013₁₀) of the cavity (3013) may be roughly flush with corresponding upper surfaces of the respective chucks (for example, the chuck (3017₁) to the chuck (3017₁₀) in FIG. 3D) in the heater (3014).

A gas (321) may flow into the cavity (3013) through the gas inlet (3012₁). A gas (322) may flow into the cavity (3013) through the gas inlet (3012₂). The gas (321) and the gas (322), for example, may be the same or different process gases, and may be respectively indicated by single arrows and single dashed-line arrows respectively shown in FIG. 3F.

Each of the base (3013₁) to the base (3013₁₀) may include a main gas inlet channel (3113) and a main gas inlet channel (3123).

The main gas inlet channel (3113) may longitudinally run through the base cover plate (3033) and the base (3013₁) to the base (3013₉) and extend into the base (3013₁₀), and include a split channel (3113₁) to a split channel (3113₆) all communicating with the main gas inlet channel (3113). The gas (321) flowing into the cavity (3013) may flow into the main gas inlet channel (3113) and the split channel (3113₁) to the split channel (3113₆), and flow to the heater (3014) through a through hole (320₁) to a through hole (320₁₁). Each of the through hole (320₁) to the through hole (320₁₁) may extends in a corresponding substrate in a direction roughly perpendicular to a principal plane. For example, the through hole (320₁) extends in the base cover plate (3033) in a direction perpendicular to the principal plane (also roughly perpendicular to the main gas inlet channel (3113)), and communicates with a row of capillary pipelines inclined downward. In this way, the gas (321) may be delivered to a surface of a wafer corresponding to the base (3013₁) through the main gas inlet channel (3113), the split channel (3113₁), as well as the through hole (320₁) and capillary pipelines thereof. It should be understood that, the through hole (320₁) and the capillary pipelines thereof are not limited to the form shown in FIG. 3F, but may be arranged in any manner or in any quantity provided that it is ensured that the gas (321) that flows in through the main gas inlet channel (3113) and the split channel (3113₁) can be delivered to the surface of the wafer corresponding to the base (3013₁).

Similarly, the main gas inlet channel (3123) may longitudinally run through the base cover plate (3033) and the base (3013₁) to the base (3013₈) and extend into the base (3013₉), and include a split channel (3123₁) to a split channel (3123₅) all communicating with the main gas inlet channel (3113). The gas (322) flowing into the cavity (3013) may flow into the main gas inlet channel (3123) and the split channel (3123₁) to the split channel (3123₅), and flow to the heater (3014) through the through hole (320₁) to the through hole (320₁₁). For example, the through hole (320₂) extends in the base (3013₁) in the direction perpendicular to the principal plane (also roughly perpendicular to the main gas inlet channel (3123)), and communicates with two rows of capillary pipelines inclined upward and downward. In this way, the gas (322) that flows in through the main gas inlet channel (3123), the split channel (3123₁), and the through hole (320₁) may be delivered to the surface of the wafer corresponding to the base (3013₁) through the capillary pipelines inclined upward and may also be delivered to a surface of a wafer corresponding to the base (3013₂) through the capillary pipelines inclined downward. It should be understood that, the through hole (320₂) and its two rows of capillary pipelines with different orientations are not limited to the form shown in FIG. 3F, but may be arranged in any manner or in any quantity provided that it is ensured that the gas (322) that flows in through the main gas inlet channel (3123) and the split channel 20) (3123₁) can be delivered to the surfaces of the wafers corresponding to the base (3013₁) and the base (3013₂).

The gas (321) and the gas (322) that flow into the cavity (3013) may further flow by an upper surface of a wafer located above each chuck of the heater (3014) (for example, flow from left to right as shown in FIG. 3F), to perform uniform coating on the surface of the wafer. In an embodiment, the gas (321) may enter the cavity (3013) before the gas (322), and then, purge the cavity (3013), and then, the gas (322) is fed. Similarly, the gas (322) may enter the cavity (3013) before the gas (321), and then, purge the cavity (3013), and then, the gas (321) is fed. In another embodiment, the gas (321) and the gas (322) may simultaneously enter the cavity (3013). It should be understood that, the foregoing application scenario may be implemented flexibly according to actual needs.

The residual gas (321) may continue flowing in a single direction (for example, transversely from left to right as shown in FIG. 3F) until the residual gas (321) is discharged out of the cavity (3013) through the gas exhaust port (3025). The residual gas (322) may continue flowing in a single direction (for example, transversely from left to right as shown in FIG. 3F) until the residual gas (321) is discharged out of the cavity (3013) through the gas exhaust port (3025).

It should be understood that, a manner of delivering a gas to upper surfaces of wafers is not limited to allocating and combining the gas (321) and the gas (322) along the split channel (3113) and the split channel (3123) as shown in FIG. 3F, and instead, the gas (321) and the gas (322) may be allocated and combined in any manner provided that it is ensured that the gas (321) and the gas (322) are delivered to the upper surfaces of the wafers.

FIG. 3G is another cross-sectional view of a cavity and a heater according to some embodiments of the present disclosure.

The heater (3014) shown in FIG. 3C and FIG. 3D may be accommodated inside the cavity (3013) shown in FIG. 3G. Upper surfaces of the base (3013₁) to the base (3013₁₀) of the cavity (3013) may be roughly flush with corresponding upper surfaces of the respective chucks (for example, the chuck (3017₁) to the chuck (3017₁₀) in FIG. 3D) in the heater (3014).

A gas (323) (indicated by a single arrow in FIG. 3G) may flow through a purge channel (3213) running through the base (3013₁) to the base (3013₁₀) and flow along an entire outer perimeter of each of the base (3013₁) to the base (3013₁₀) (which is illustrated in FIG. 3H and below in detail), and finally, be discharged out of the cavity (3013) through the gas exhaust port (3025). The gas (323), for example, may be a purge gas.

The gas (323) may purge each of the base (3013₁) to the base (3013₁₀), to prevent article contamination from being formed inside the cavity (3013) due to process gas leakage.

FIG. 3H is a top view of a base according to some embodiments of the present disclosure.

Because each of the base (3013₁) to the base (3013₁₀) may have a substantially same structure, only the base (3013₁) is shown in FIG. 3H as an example to illustrate a top view structure of the base.

Referring to FIG. 3H, for example, the gas (323) that may be the purge gas (indicated by a single arrow in FIG. 3H) may flow through the purge channel (3213) running through the base (3013₁) and flow along the entire outer perimeter of the base (3013₁) (indicated by a single arrow in FIG. 3H), and further, be discharged out of the cavity through the gas exhaust port (3025).

A notch (3413) located in the middle of the base (3013₁) can be configured to accommodate, for example, the heater (3014) shown in FIG. 3C and FIG. 3D.

In this way, particles formed within the cavity due to process gas leakage may be discharged out of the cavity with the gas (323).

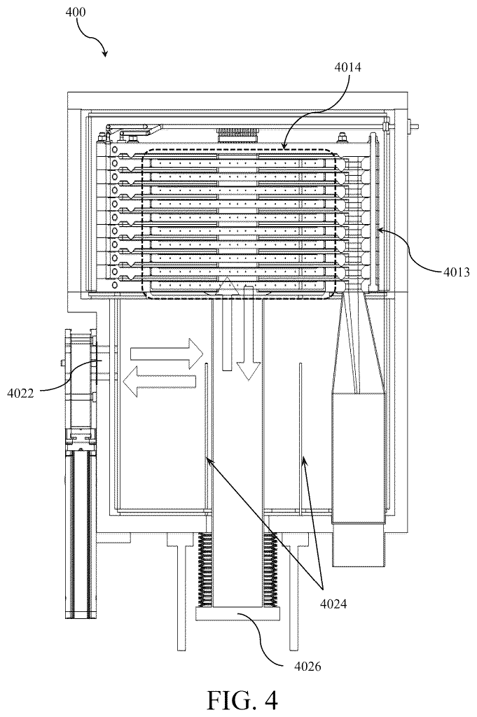

FIG. 4 is a schematic diagram of operation of a semiconductor device according to some embodiments of the present disclosure.

Referring to FIG. 4, in a semiconductor device (400), a heater (4014) may be moved longitudinally into or out of a cavity (4013) under the action of a mechanism (4026) (indicated by up and down arrows in FIG. 4).

First, the mechanism (4026) may move downward to drive the heater (4014) to move out of the cavity (4013) and move into the vicinity of a wafer delivery port (4022).

Then, a to-be-processed wafer may be delivered to a chuck of the heater (4014) through the wafer delivery port (4022) under the action of, for example (but not limited to), a robotic arm and supported by a jacking rod (4024). Further, the jacking rod (4024) is controlled to fall, to place the wafer smoothly on a surface of the chuck. It should be understood that, the operations may be cyclically to deliver a plurality of to-be-processed wafers to a plurality of chucks of the heater (4014).

After all the wafers have been moved into the heater (4014), the mechanism (4026) may move upward and drive the heater (4014) to move into the cavity (4013), to perform a wafer coating process.

After completing the wafer coating process, the mechanism (4026) may move downward again, to move the heater (4014) out of the cavity (4013) and enables the heater (4014) to move into the vicinity of the wafer delivery port (4022).

Next, the jacking rod (4024) may be controlled to rise to jack the processed wafer away from the surface of the chuck, and the wafer may be moved out of the heater (4014) through the wafer delivery port (4022) by, for example (but not limited to), the robotic arm.

The semiconductor device provided by the embodiments of the present disclosure has a multi-layer cross-flow structure, which can not only greatly increase the production capacity, but also keep gas flows in a unified direction, so that the wafer coating efficiency can be improved while ensuring the uniformity of the film.

Moreover, while performing heating and/or preheating using the inner wall heater of the cavity, the multi-layer heater structure provided by the embodiments of the present disclosure can independently heat each wafer, thereby greatly improving the temperature uniformity between wafers and ensuring the uniformity of the film.

In addition, because the multi-layer heater structure provided by the embodiments of the present disclosure can provide a corresponding and independent heating chuck for each wafer, each wafer has only one surface (for example, an upper surface) exposed to a reactive gas, which, therefore, is especially suitable for application of performing coating on a single surface of a wafer.

As used in the present application, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” usually means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

For example, when being used in combination with a value, the term may refer to a variation range of less than or equal to ±10% of the value, for example, less than or equal to ±5%, less than or equal to ±4%, less than or equal to ±3%, less than or equal to #2%, less than or equal to ±1%, less than or equal to ±0.5%, less than or equal to ±0.1%, or less than or equal to ±0.05%. For example, if a difference between two values is less than or equal to ±10% of an average value of the values (for example, less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%), it may be considered that the two values are “substantially” or “approximately” the same. For example, being “basically” parallel may refer to an angular variation range of less than or equal to #10° with respect to 0°, for example, less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, being “basically” perpendicular may refer to an angular variation range of less than or equal to ±10° with respect to 90°, for example, less than or equal to ±5°, less than or equal to ±4°, less than or equal to ±3°, less than or equal to ±2°, less than or equal to #1°, less than or equal to ±0.5°, less than or equal to ±0.1°, or less than or equal to =0.05°.

For example, two surfaces can be considered to be coplanar or substantially coplanar if the displacement between the two surfaces is equal to or less than 5 μm, equal to or less than 2 μm, equal to or less than 1 μm, or equal to or less than 0.5 μm. A surface can be considered to be planar or substantially planar if the displacement between any two points on the surface with respect to a plane is equal to or less than 5 μm, equal to or less than 2 μm, equal to or less than 1 μm, or equal to or less than 0.5 μm.

As used herein, unless otherwise explicitly stated in the context, singular terms “a/an” and “the” may include plural indicators. In the description of some embodiments, a component provided “on” or “above” another component may encompass a case in which the former component is directly on the latter component (for example, in physical contact with the latter component), and a case in which one or more intermediate components are located between the former component and the latter component.

As used herein, for ease of description, spatially relative terms such as “under”, “below”, “lower portion”, “above”, “upper portion”, “lower portion”, “left side”, and “right side” may be used herein to describe a relationship between one component or feature and another component or feature as shown in the figures. In addition to orientations shown in the figures, the spatially relative terms are intended to encompass different orientations of the device in use or operation. An apparatus may be oriented in other ways (rotated 90 degrees or at other orientations), and the space-related descriptors used herein may also be used for explanation accordingly. It should be understood that when a component is referred to as being “connected” or “coupled” to another component, the component may be directly connected to or coupled to the another component, or an intermediate component may exist.

Several embodiments of the disclosure and features of details are briefly described above. The embodiments described in the present disclosure may be easily used as a basis for designing or modifying other processes and structures for realizing the same or similar objectives and/or obtaining the same or similar advantages introduced in the embodiments of the present disclosure. Such equivalent construction does not depart from the spirit and scope of the disclosure, and various variations, replacements, and modifications can be made without departing from the spirit and scope of the disclosure.

1. A semiconductor device, comprising:
a first base, comprising a front surface and a back surface, and comprising a first main gas inlet channel, a second main gas inlet channel, a first split channel, and a first through hole;
a second base, connected to the back surface of the first base, and comprising the first main gas inlet channel, the second main gas inlet channel, a second split channel and a second through hole; and
a base cover plate, connected to the front surface of the first base, and comprising the first main gas inlet channel, the second main gas inlet channel, a third split channel, and a third through hole, the base cover plate receiving a first gas through the first main gas inlet channel and receiving a second gas through the second main gas inlet channel, wherein
the first gas and the second gas are delivered to the front surface of the first base through the first through hole and the third through hole, and the first gas and the second gas are delivered to the back surface of the first base through the first through hole and the second through hole.

2. The semiconductor device according to claim 1, wherein the first main gas inlet channel and the second main gas inlet channel run through the base cover plate, the first base, and the second base.

3. The semiconductor device according to claim 1, wherein the first through hole, the second through hole, and the third through hole communicate with the front surface and the back surface of the first base through one or more capillary pipelines.

4. The semiconductor device according to claim 1, further comprising a heating device, the heating device comprising:
a first chuck, comprising a first surface and a second surface opposite to the first surface; and
a second chuck, connected to the first chuck, and comprising a third surface and a fourth surface opposite to the third surface, the third surface being separated from the second surface.

5. The semiconductor device according to claim 4, wherein the first surface of the first chuck is configured to be coplanar with the front surface of the first base.

6. The semiconductor device according to claim 4, wherein the third surface of the second chuck is configured to be coplanar with the back surface of the first base.

7. The semiconductor device according to claim 4, further comprising:
a first heating element, arranged inside the first chuck; and
a second heating element, arranged inside the second chuck.

8. The semiconductor device according to claim 7, wherein the first heating element and the second heating element are configured to heat the first chuck and the second chuck independently.

9. The semiconductor device according to claim 4, wherein the first heating element and the second heating element are led from the first surface of the first chuck.

10. The semiconductor device according to claim 4, further comprising a first wafer, the first wafer being placed on the first surface of the first chuck.

11. The semiconductor device according to claim 4, further comprising a second wafer, the second wafer being placed on the third surface of the second chuck.

12. A semiconductor device, comprising:
a gas inlet, configured to receive one or more gases;
a cavity, connected to the gas inlet and comprising a plurality of bases;
a gas outlet, communicating with the plurality of bases inside the cavity; and
a heating device, arranged inside the plurality of bases of the cavity, the heating device comprising a plurality of chucks, the plurality of chucks being arranged corresponding to the plurality of bases, to enable the one or more gases to flow by the plurality of bases and the plurality of chucks into the gas outlet.

13. The semiconductor device according to claim 12, wherein the heating device further comprises a heating element located inside each of the plurality of chucks.

14. The semiconductor device according to claim 12, wherein the heating device is configured to move relative to the cavity.

15. The semiconductor device according to claim 13, wherein the heating element inside each of the plurality of chucks is configured to heat the plurality of chucks independently.

16. The semiconductor device according to claim 12, wherein the cavity comprises a main gas inlet channel running through the cavity and a split channel communicating with the main gas inlet channel, the one or more gases flowing by the plurality of bases and the plurality of chucks through the main gas inlet channel and the split channel and flowing into the gas outlet.

17. The semiconductor device according to claim 12, wherein the cavity comprises a purge channel running through the cavity, the one or more gas purging the plurality of bases through the purge channel and flowing into the gas outlet.

18. The semiconductor device according to claim 12, wherein the cavity further comprises an inner wall heater, the inner wall heater being configured to preheat a wafer located inside the heating device.

19. A semiconductor processing method, comprising:
processing surfaces of a plurality of wafers using the semiconductor device according to claim 12.
